(19) United States
(12) Patent Application Publication
(10) Pub. No.: US 2025/0293169 A1
(43) Pub. Date: Sep. 18, 2025

(54) STACKABLE POWER SEMICONDUCTOR MODULE

(71) Applicant: ZF Friedrichshafen AG, Friedrichshafen (DE)

(72) Inventors: Ake Ewald, Hamburg (DE); Fabian Hohmann, Hofbieber (DE)

(73) Assignee: ZF Friedrichshafen AG, Friedrichshafen (DE)

(21) Appl. No.: 19/082,925

(22) Filed: Mar. 18, 2025

(30) Foreign Application Priority Data
Mar. 18, 2024 (DE) 10 2024 202 527.5

(51) Int. Cl. H01L 23/538; H01L 23/15; H01L 23/31; H01L 23/373; H01L 25/18

(52) U.S. Cl. CPC H01L 23/5385; H01L 23/3735; H01L 25/18; H01L 23/15; H01L 23/3121

(57) ABSTRACT

A module for an inverter having first and second flat power semiconductors in a half bridge circuit, each having a drain connection on a first side and a source connection on the other side. The first side of the first power semiconductor faces the same direction as the second side of the second power semiconductor. A lower contact module thermally connects the first side of the first semiconductor and second side of the second semiconductor to a lower heat sink and electrically connects the drain on the first semiconductor to a first DC input and the source on the second semiconductor to a second DC input. An upper contact module thermally connects the second side of the first semiconductor and first side of the second semiconductor to an upper heat sink and electrically connects the source on the first semiconductor and drain on the second semiconductor to an AC output.

### CROSS-REFERENCE TO RELATED APPLICATION

This application claims priority to German Patent Application No. 10 2024 202 527.5 filed on Mar. 18, 2024, the entirety of which is hereby fully incorporated by reference herein.

### TECHNICAL FIELD

The present disclosure relates to a module for an inverter. The present disclosure also relates to an inverter module for an inverter, and an inverter.

### BACKGROUND

Power electronics in electric and hybrid vehicles conduct traction power from the battery to the electric motor, converting direct current into alternating current. This requires an AC converter, i.e. an inverter or traction inverter. Numerous transistors or power semiconductors are normally used for this, forming a power semiconductor module, which are switched on and off in short, regular intervals. In particular, metal-oxide-semiconductor field-effect transistors (MOSFETs) or insulated-gate bipolar transistors (IGBTs) and junction field-effect transistors (JFETs) are used for this. When switched on, current is conducted from the battery to the motor (conducting phase). As a result of this high-frequency switching, a voltage curve in the alternating current is obtained which can then be used in the electric motor as traction power. Numerous power semiconductors are usually connected in parallel in order to increase the ampacity.

Comparatively high currents are switched on and off with these power semiconductor modules, or power semiconductors, thus generating a lot of heat. Active or passive cooling systems are usually used to discharge the heat from the power semiconductors to another medium through a heat sink. These modules for inverters therefore contain contact modules in addition to the power semiconductors, with which electrical and thermal contact to the power semiconductors and cooling structures is obtained. This results in a heat-conducting path from the power semiconductors to a coolant. The heat-conducting path (thermal path) normally has electrically insulating layers that electrically insulate the cooling structure.

In the prior art, modules have been obtained in which individual power semiconductors have contacts for discharging heat on one or both sides.

A current approach in this context cools the power semiconductors from both sides to improve the cooling effect. A module, vehicle, method for the use thereof and a method for manufacturing the module are disclosed in DE 10 2016 121 801 A1. The device contains at least one electronic chip. It also contains at least one heat sink to which the at least one chip is bonded. The module also has a second heat sink to which the at least one chip is bonded. The module is also encased in a material that encases at least part of the at least one chip, part of the first heat sink, and part of the second heat sink. The first bond has a different melting temperature than the second.

A disadvantage with prior approaches is that the heat transfer is often less than optimal, which can have a negative impact on the conductivity of the semiconductors. It is also challenging to manufacture them efficiently, in that multi-step production methods often lead to higher costs or are more complicated. Moreover, semiconductor modules frequently have specific requirements regarding the necessary installation space, thus limiting where they can be used.

### SUMMARY

Based on this, an object of the present disclosure is to create a power semiconductor that can be used and cooled efficiently. In particular, a power semiconductor module should be obtained that can be used in a variety of applications and can be cooled efficiently and reliably. Moreover, it should possible to manufacture the module efficiently, to reduce costs.

To achieve this, a first aspect of the present disclosure relates to a module for an inverter that has:
a first flat power semiconductor and a second flat power semiconductor, each of which has a drain connection on a first side and a source connection on the other side, in which the two power semiconductors are in a half bridge circuit and the first side of the first power semiconductor faces in the same direction as the second side of the second power semiconductor;
a lower contact module for thermally connecting the first side of the first power semiconductor and the second side of the second power semiconductor to a lower heat sink and electrically connecting the drain on the first power semiconductor to a first DC input and the source on the second power semiconductor to a second DC input; and
an upper contact module for thermally connecting the second side of the first power semiconductor and the first side of the second power semiconductor to an upper heat sink and electrically connecting the source on the first power semiconductor and the drain on the second power semiconductor to an alternating current output.

Another aspect of the present disclosure relates to an inverter module for an inverter with two or more modules, as described above, in which the two or more modules are stacked perpendicular to the flat power semiconductors; and
a heat sink is placed between each of the modules in the assembly, such that a lower contact module on a first module and an upper contact module on a second module are thermally connected to the same heat sink.

Another aspect of the present disclosure relates to an inverter for an electric vehicle that contains the module described above, or an inverter module like that describe above.

Preferred embodiments of the present disclosure are described herein. It is understood that the features specified above and described below can be used not only in the given combinations, but also in other combinations or in and of themselves, without abandoning the scope of the present disclosure. In particular, the modules, inverter modules, and inverter can be designed in accordance with the embodiments described for the modules and inverter modules herein.

With the present disclosure, there are two power semiconductors (chips) in a half bridge circuit. These power semiconductors are flat, such that their widths and lengths are greater than their thicknesses. The power semiconductors are identical, and have a first connection (drain) on one side (outer surface) and a second connection (source) on the other side (opposite outer surface). One of the power semiconductors in each module is inverted in relation to the other. An upper surface of the first power semiconductor thus faces in the same direction as the lower surface of second power semiconductor. In other words, one power semiconductor is inverted, or turned upside-down. The drain for the one power semiconductor faces the same direction as the source on the other power semiconductor.

The two power semiconductors are contacted in the module from both sides, i.e. top and bottom, by two contact modules. These contact modules establish not only the thermal connection, for discharging heat, but also the electrical connection, for receiving DC voltage and emitting AC voltage. The electric half bridge circuit contains two DC inputs (DC+, DC−) and an AC output (AC). The inputs and output are connected to the drain and source connections on the power semiconductors. In this regard, one power semiconductor forms a topological high side switch and the other forms a topological low side switch. The thermal contact is also obtained on the upper and lower sides of the power semiconductors by the contact modules, each of which is connected to a dedicated heat sink.

Unlike with prior approaches, there are therefore two power semiconductors in the module obtained with the present disclosure, which are thermally and electrically connected to one another by upper and lower contact modules. The structure of the module obtained with the present disclosure results in a compact power core. In particular, it is possible to stack numerous modules on top of one another (vertically, in relation to the direction in which the flat power semiconductors extend). This results in a compact design. Furthermore, it can be easily scaled. For some installation spaces, expansion in this direction is necessary to reach compatibility. Cooling the power semiconductors from both sides lowers the thermal resistance, thus raising the performance level. The stacking of different modules in the inverter module obtained with the present disclosure allows for compatibility with various requirements, as well as compliance with different performance demands. This results in an efficient production that is both flexible and variable.

In a preferred embodiment, the lower contact module and/or upper contact module form a direct bonded copper (DBC) structure. A DBC structure results in a narrow electrical and thermal connection between power semiconductors and contact modules. This results in an efficient means of cooling. Electrical insulation is obtained with an insulating layer (preferably ceramic). Conductor paths and contact surfaces can be formed on the DBC substrate, resulting in efficient cooling and good electrical contact. This can be efficiently produced with a high conductivity.

In a preferred embodiment, the contact modules each have a first copper layer on a side facing the power semiconductors and a second copper layer on a side facing the heat sink, as well as ceramic layer therebetween. The DBC substrate structure, comprising two copper layers with a ceramic layer therebetween, results in an efficient means of obtaining electrical contact, and an effective thermal connection. Furthermore, the ceramic layer forms an electrical insulator. This can be efficiently produced with high conductivity.

In a preferred embodiment, the mechanical stability of the module is improved by a casting compound from which thermal and electrical contacts for the contact modules protrude. In particular, a casting compound can be used for this. This results in an electrical insulation. By way of example, a polymer compound can be used. The casting compound reinforces the structure and protects it against mechanical effects.

In a preferred embodiment, the two power semiconductors are adjacent to one another. This means that they are substantially in the same plane. They may be slightly offset to one another along the vertical axis, to obtain different source and drain sides of the power semiconductors. This reduced spacing results in a compact structure. It can be produced efficiently and readily scaled.

A preferred embodiment of the inverter module obtained with the present disclosure contains two more stacked groups. The three stacks are for the three phases of an electric motor, and adjacent to one another. This means that they are aligned vertically, in a direction orthogonal to the flat power semiconductors. They are therefore offset along the surface of the flat power semiconductors. Use of three stacks for the three phases of the electric motor makes efficient use of space.

In a preferred embodiment of the inverter module, the three contact modules for the three stacks are thermally connected to the same heat sink. It is advantageous to connect the lower contact modules to the same lower heat sink and the upper contact modules to the same upper heat sink. This results in two heat sinks, one of which is the lower heat sink, while the other is the upper heat sink. This makes efficient use of space. It can also be produced inexpensively.

In a preferred embodiment of the inverter module, the electrical contacts protrude laterally from the contact modules on the two, three, or more modules in a stack, parallel to the flat power semiconductors. The electrical contacts for the first DC input and second DC input are preferably on a first side of the stack, and an electrical contact for the AC output is on a second side of the stack. This also makes efficient use of space. It also results in an efficient contact to the half bridge circuit through these contacts. It can be efficiently installed.

In a preferred embodiment of the inverter module, there is a half bridge capacitor above or below the stack. The stacking direction is parallel to the vertical axis of the individual power semiconductors. Placing the capacitor above or (preferably) below the stack makes efficient use of space. The capacitor can also be placed in a different direction to enable parallel switching of the half bridges to counteract misdistribution of the current.

A sintered bond can be formed between the individual layers of the contact modules, and between the contact modules and power semiconductors. Sintering results in a material bond that is thermally conductive.

An inverter module in this context is a module intended for use in an inverter or inverter structure. Numerous power semiconductors are normally combined to obtain a power semiconductor module. A power semiconductor module normally contains numerous power semiconductors and can also be referred to as a module. A power semiconductor is an electronic chip that has one or more integrated circuit components. Specifically, a power semiconductor is a transistor. MOSFETs, IGBTs, and JFETs can be used as power semiconductors. Numerous identical or different power semiconductors can be combined in a module, or power semiconductor module. Specifically, a power semiconductor module is a semiconductor switch. The terms, “lower” and “upper” in conjunction with the different modules or elements are only used for purposes of clarity and distinction. It is understood that the modules can also be inverted, or turned upside-down. The same applies to the distinction between “first” and “second.” A first side and second side of a flat semiconductor are the opposite outer surfaces of the power semiconductor that are the largest. The module obtained with the present disclosure is intended for use in a vehicle, or in an inverter module for a vehicle. A flat design in this context means that the structure extends along two axes substantially further than along a third (vertically).

The present disclosure shall be explained and described in greater detail below in reference to a selected exemplary embodiment in reference to the drawings.

### BRIEF DESCRIPTION OF THE DRAWINGS

FIG. 1 shows a schematic illustration of a vehicle that has an inverter and a module obtained with the present disclosure;

FIG. 2 shows a schematic illustration of a thermal path from a semiconductor to a coolant in a module according to the prior art;

FIG. 3 shows a schematic illustration of a module obtained with the present disclosure in a sectional view parallel to a plane of the power semiconductor;

FIG. 4 shows a schematic illustration of a module obtained with the present disclosure in a sectional view along a plane that is orthogonal to a plane of the power semiconductor;

FIG. 5 shows a corresponding sectional view in a plane perpendicular to the planes in FIGS. 3 and 4; and

FIG. 6 shows a schematic illustration of an embodiment of the inverter module obtained with the present disclosure, which has three stacks for the three phases of an electric motor.

### DETAILED DESCRIPTION

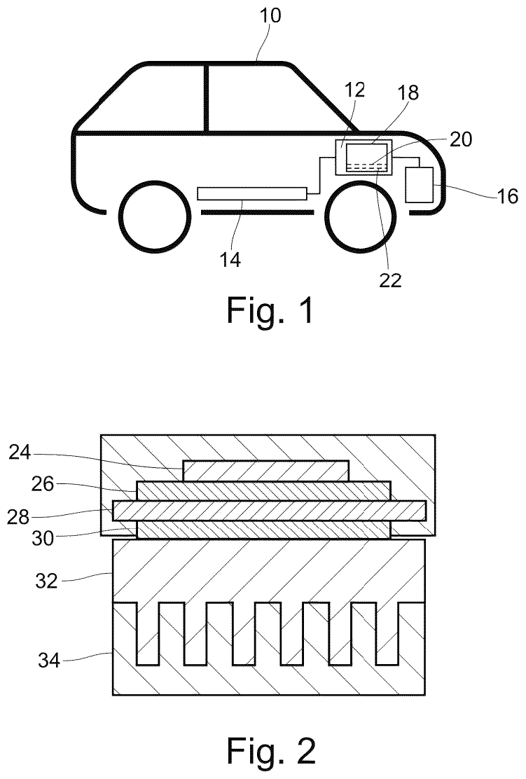

FIG. 1 shows a schematic illustration of a vehicle 10 with an inverter 12 obtained with the present disclosure. The inverter 12 is between a battery 14 and an electric machine 16 in the vehicle 10, to convert the direct current from the battery 14 into the alternating current needed by the electric machine 16. The inverter 12 contains an inverter module 18 in which there are three stacks 20, each of which contains two modules 22. The modules 22 each contain the power semiconductors, or semiconductor switches, which can be formed by MOSFETs, in particular. This illustration is schematic, and for purposes of clarity, some components are not shown.

With current inverters, the semiconductor switches (power semiconductors) must be actively cooled in order to drain off switching and performance losses. A thermal path is created from the semiconductors to a coolant for this. This thermal path contains the components shown in FIG. 2 in modules from the prior art.

To cool the power semiconductors 24, they are placed on an upper copper layer 26, which in turn is on a ceramic layer 28 and a lower copper layer 30. This forms a direct bonded copper (DBC) structure. The DBC structure is on a cooling plate 32 (heat sink) that is in contact with the coolant 34. The thermal path from the power semiconductors 24 to the coolant 34 is formed with the various components, and the DBC structure forms an electrically insulating layer.

The thermal resistance, i.e. the combined thermal resistances of the individual components in FIG. 2, has a large effect on the performance of the semiconductors. Instead of the meandering structure for the cooling plate 32 shown in FIG. 2, pin-fin structures can also be used.

To optimize the thermal path, the thermal resistance must be minimized. At this point, there are electrically necessary resistances, e.g. insulating the ceramic layer 28, and resistances necessary for production purposes. The latter include the resistances of the copper layers 26, 30, which are necessary for structural and connecting purposes, the thicknesses of which can be optimized for thermal conductance. The copper plate 32 also has a resistance necessary for production purposes, which cannot be optimized for thermal conductance due to production and assembly limitations. There is also a resistance in the transition between the cooling plate 32 and coolant that is necessary for production purposes, which is also greater than technically necessary, due to production and assembly limitations.

The production and assembly limitations for the cooling plate 32 and the transition to the coolant 34 are determined by the production process, the cooling plate 32 with its cooling structure, and the assembly process, which normally comprises sintering the DBC to the cooling plate. A compression process is often used during production, in which minimal thicknesses of the cooling plates must be maintained. Moreover, the structure of the cooling structure, or cooling plate, is limited by minimum spacings, diameters, and the shapes, e.g. of the pins. A pressure of 10 to 20 MPa is required for sintering, which has an effect on the thickness of the cooling plate. Furthermore, the tool used for this must be shaped such that it can withstand these pressures, because the cooling structure itself normally cannot. This is normally obtained with a negative shape corresponding to that of the cooling structure.

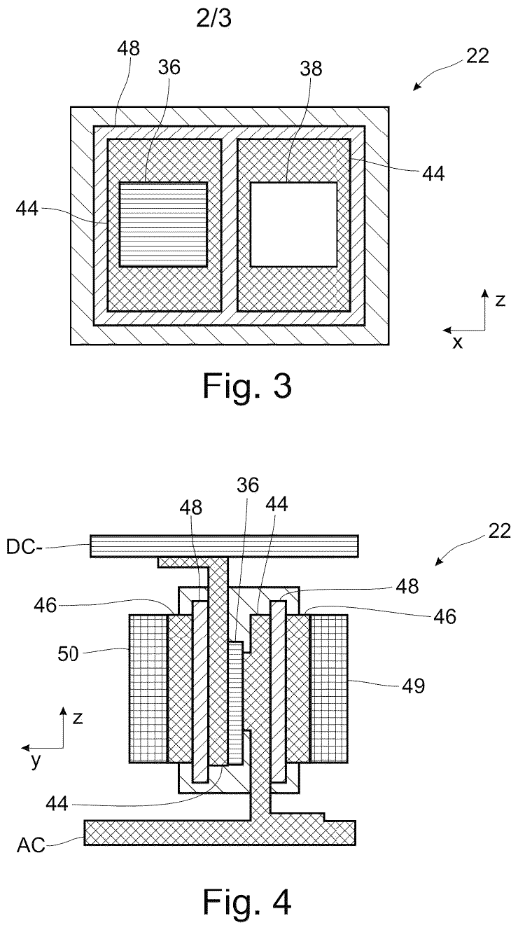

FIGS. 3, 4, and 5 show schematic illustrations of an exemplary embodiment of the module 22 obtained with the present disclosure. Specifically, they show three different sectional views of the module 22. This module 22 contains a first flat power semiconductor 36, a second flat semiconductor 38, a lower contact module 40, and an upper contact module 42. The y-axis in these illustrations is parallel to the vertical direction of the flat power semiconductors 36, 38, and orthogonal to the plane in which the power semiconductors lie. The x and z-axes form the plane in which the flat power semiconductors 36, 38 lie.

It is particularly advantageous to use a DBC substrate, which has two electrically insulated power semiconductors 36, 38, which are identical but inverted in relation to one another. The orientation of the power semiconductors 36, 38 is such that the drain connection on a first side of the first power semiconductor 36 faces downward, and forms the topological low side switch. The second side, or source surface of the second power semiconductor 38 faces downward, and forms the topological high side switch. There is a contact module on each side (first and second sides, i.e. drain and source sides) formed by a lower contact module 40 and an upper contact module 42. There is also a lower heat sink 49 and an upper heat sink 50. In particular, each contact module 40, 42 can have a first copper layer 44 on the side facing the power semiconductors 36, 38, and a second copper layer 46 on the side facing the heat sinks 49, 50. There is a ceramic layer 48 between the copper layers 44, 46 that electrically insulates them. There is also a casting compound 52, which reinforces the overall structure. The contacts extend from the casting compound 52.

A FIG. 3 in particular shows, the two power semiconductors 36, 38 are adjacent to one another. These power semiconductors are substantially in the same plane.

The electrical contact can be seen in FIG. 4 in particular. A DC input is on one side, and an AC output is on the other. The second power semiconductor is behind the first power semiconductor 36. The connection to the DC side can be at the end of the z-axis.

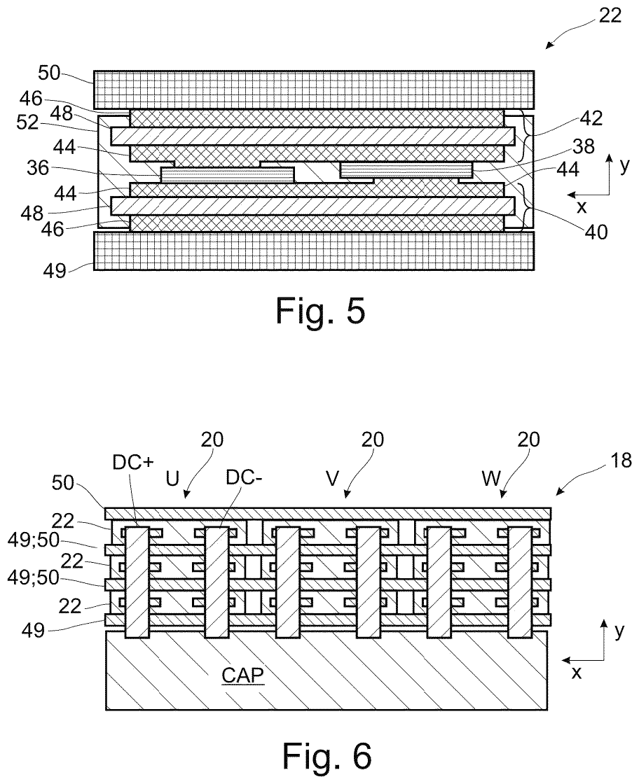

FIG. 5 shows in particular that the two power semiconductors 36, 38 are parallel.

FIG. 6 shows a schematic illustration of a preferred embodiment of the inverter module 18 obtained with the present disclosure. This inverter module 18 has three stacks 20 for the three phases u, v, w of an electric motor, which are adjacent to one another. Each stack 20 in this exemplary embodiment contains three modules 22. There is a heat sink 49, 50 between each pair of modules 22. In other words, the lower heat sink 49 for the upper module 22 is the upper heat sink 50 for the module 22 below it.

In this exemplary embodiment, shown in FIG. 6, the three contact modules for the three stacks 20 (the parallel contact modules in the three stacks) are thermally connected to the same heat sinks 49, 50. In particular, one heat sink can extend through all three stacks, thus cooling numerous different modules 22.

Electrical contacts are also shown in FIG. 6, in which the two DC inputs DC+ and DC− are on the same sides of the stacks 20.

FIG. 6 also shows a half bridge capacitor cap underneath the different stacks 20.

The present disclosure has been comprehensively described and explained in reference to the drawings. The descriptions and explanations are exemplary and not to be regarded as limiting. The present disclosure is not limited to the embodiments disclosed herein. Other embodiments or variations can be derived by the person skilled in the art when using this present disclosure, or through a precise analysis of the drawings, the disclosure and the following claims.

The terms, “comprising” and “with,” in the claims do not exclude the presence of other elements or steps. The indefinite articles “a” and “an” do not exclude the presence of a plurality. A single element or unit can function as numerous units specified in the claims. An element, unit, interface, apparatus, or system can be implemented partially or entirely as hardware and/or software. Simply specifying certain measures in numerous dependent claims is not to be understood to mean that a combination of these measures cannot also be advantageously used. A computer program can be stored/executed on a non-volatile data storage medium, e.g. an optical memory or a solid-state drive (SSD). A computer program can be distributed along with hardware and/or as part of hardware, e.g. through the internet, or using hard-wired or wireless communication systems. The reference symbols in the claims are not to be understood as limiting.

### REFERENCE SYMBOLS

10 vehicle
12 inverter
14 battery
16 electric machine
18 inverter module
20 stack
22 module
24 power semiconductor
26 upper copper layer
28 ceramic layer
30 lower copper layer
32 cooling plate
34 coolant
36 first power semiconductor
38 second power semiconductor
40 lower contact module
42 upper contact module
44 first copper layer
46 second copper layer
48 ceramic layer
49 lower heat sink
50 upper heat sink
52 casting compound

1. A module for an inverter, comprising:
a first flat power semiconductor and a second flat power semiconductor, each of which comprises a drain connection on a first side and a source connection on a second side, wherein the two power semiconductors are in a half bridge circuit, and the first side of the first power semiconductor faces in a same direction as the second side of the second power semiconductor;
a lower contact module configured to thermally connect the first side of the first power semiconductor and the second side of the second power semiconductor to a lower heat sink, and to electrically connect the drain on the first power semiconductor to a first DC input, and the source on the second power semiconductor to a second DC input; and
an upper contact module configured to thermally connect the second side of the first power semiconductor and the first side of the second power semiconductor to an upper heat sink, and to electrically connect the source on the first power semiconductor and the drain on the second power semiconductor to an AC output.

2. The module according to claim 1,
wherein the lower contact module and/or the upper contact module are direct bonded copper structures.

3. The module according to claim 1,
wherein the lower contact module and the upper contact module each have a first copper layer on a side facing the power semiconductors, and a second copper layer on a side facing the heat sinks, as well as a ceramic layer between the first and second copper layers.

4. The module according to claim 1, comprising:
a casting compound configured to mechanically reinforce the module, wherein thermal and electrical contacts for the upper and lower contact modules protrude from the casting compound.

5. The module according to claim 1,
wherein the first flat power semiconductor and the second flat power semiconductor are adjacent to one another.

6. An inverter module for an inverter comprising:
two or more modules according to claim 1, comprising a first module and a second module,
wherein the two or more modules are stacked in a direction perpendicular to the flat power semiconductors, and form a stack, and
wherein a heat sink is placed between the first and second modules in a stack, such that the lower contact module for the first module, and the upper contact module for the second module are thermally connected to a same heat sink.

7. The inverter module according to claim 6, comprising:
three stacks, wherein the three stacks are for three phases of an electric motor, and are adjacent to one another.

8. The inverter module according to claim 7,
wherein three contact modules for the three stacks are thermally connected to a same heat sink.

9. The inverter module according to claim 6,
wherein electrical contacts in the contact modules for the two or more modules in each stack extend laterally from the stacks, parallel to the flat power semiconductors, and
wherein electrical contacts for the first DC input and second DC input are on a first side of the stacks, and electrical contacts for the AC outputs are on a second side of the stacks.

10. The inverter module according to claim 6,
wherein a half bridge capacitor is placed above or below the stacks.

11. An inverter for an electric vehicle comprising:
the module according to claim 1.

12. The module according to claim 3, comprising:
a casting compound configured to mechanically reinforce the module, wherein thermal and electrical contacts for the upper and lower contact modules protrude from the casting compound.

13. The module according to claim 3,
wherein the first flat power semiconductor and the second flat power semiconductor are adjacent to one another.

14. An inverter module for an inverter comprising:
two or more modules according to claim 3, comprising a first module and a second module,
wherein the two or more modules are stacked in a direction perpendicular to the flat power semiconductors, and form a stack, and
wherein a heat sink is placed between the first and second modules in a stack, such that the lower contact module for the first module, and the upper contact module for the second module are thermally connected to a same heat sink.

15. The module according to claim 4,
wherein the first flat power semiconductor and the second flat power semiconductor are adjacent to one another.

16. An inverter module for an inverter comprising:
two or more modules according to claim 4, comprising a first module and a second module,
wherein the two or more modules are stacked in a direction perpendicular to the flat power semiconductors, and form a stack, and
wherein a heat sink is placed between the first and second modules in a stack, such that the lower contact module for the first module, and the upper contact module for the second module are thermally connected to a same heat sink.
